(19) United States
(12) Patent Application Publication
(10) Pub. No.: US 2025/0216415 A1
(43) Pub. Date: Jul. 3, 2025

(54) PROBE

(71) Applicant: YOKOWO CO., LTD., Tokyo (JP)

(72) Inventor: Takuya HAYASHI, Tomioka-shi, Gunma (JP)

(73) Assignee: YOKOWO CO., LTD., Tokyo (JP)

(21) Appl. No.: 18/850,058

(22) PCT Filed: Mar. 13, 2023
(86) PCT No.: PCT/JP2023/009487

§ 371 Date: Sep. 24, 2024

(30) Foreign Application Priority Data
Mar. 25, 2022 (JP) 2022-049368

(51) Int. Cl. G01R 1/067; G01R 3/00

(52) U.S. Cl. CPC G01R 1/06722; G01R 3/00

(57) ABSTRACT

A probe including a plunger, and a barrel provided with an opening through which at least a part of the plunger protrudes, and an inner surface of the opening is substantially parallel to an axial direction of the plunger.

### TECHNICAL FIELD

The present invention relates to a probe.

### BACKGROUND ART

In recent years, various probes have been developed. The probe includes a barrel and a plunger. The barrel includes a locking portion for locking the probe. The locking portion is provided with an opening through which at least a part of the plunger protrudes. For example, in a probe described in Patent Document 1, a locking portion is formed by caulking one end of the barrel.

### RELATED DOCUMENT

### Patent Document

Patent Document 1: Japanese Unexamined Patent Publication No. 2021-43100

### SUMMARY OF THE INVENTION

### Technical Problem

For example, as described in Patent Document 1, the locking portion may be formed by caulking. In this case, an inner surface of an opening provided in the locking portion may be inclined with respect to a central axis of the probe. Accordingly, a plunger is likely to be inclined with respect to the central axis of the probe.

An example of an object of the present invention is to suppress inclination of the plunger with respect to the central axis of the probe. Other objects of the present invention will become apparent from the description of this specification.

### Solution to Problem

An aspect of the present invention is a probe including:
a plunger; and
a barrel provided with an opening through which at least a part of the plunger protrudes,
in which an inner surface of the opening is substantially parallel to an axial direction of the plunger.

According to the above-described aspect of the present invention, it is possible to suppress the inclination of the plunger with respect to the central axis of the probe.

### BRIEF DESCRIPTION OF THE DRAWINGS

FIG. 1 A cross-sectional view of a probe head according to an embodiment.

FIG. 2 A cross-sectional view of a part of a probe according to the embodiment.

FIG. 3 A cross-sectional view of a barrel according to a comparative embodiment.

FIG. 4 A diagram illustrating a method of manufacturing a barrel according to the embodiment.

FIG. 5 A diagram illustrating the method of manufacturing the barrel according to the embodiment.

FIG. 6 A diagram illustrating the method of manufacturing the barrel according to the embodiment.

FIG. 7 A diagram illustrating the method of manufacturing the barrel according to the embodiment.

### DESCRIPTION OF EMBODIMENTS

Hereinafter, an embodiment of the present invention will be described with reference to the drawings. In all the drawings, the same constituent elements are denoted by the same reference signs, and the description thereof will not be repeated.

In this specification, unless otherwise specified, ordinal numbers such as “first”, “second”, “third”, and the like are added merely to distinguish similarly termed configurations and do not imply any particular feature (for example, an order or importance) of the configurations.

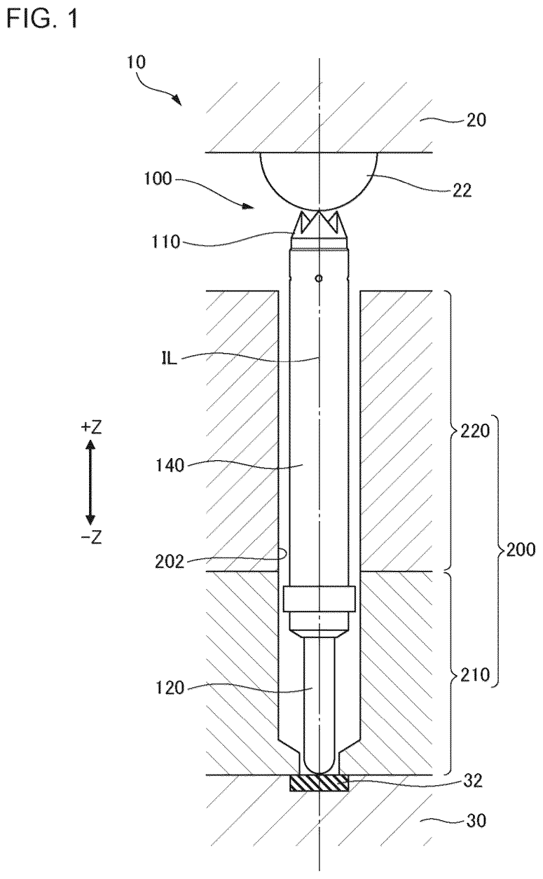

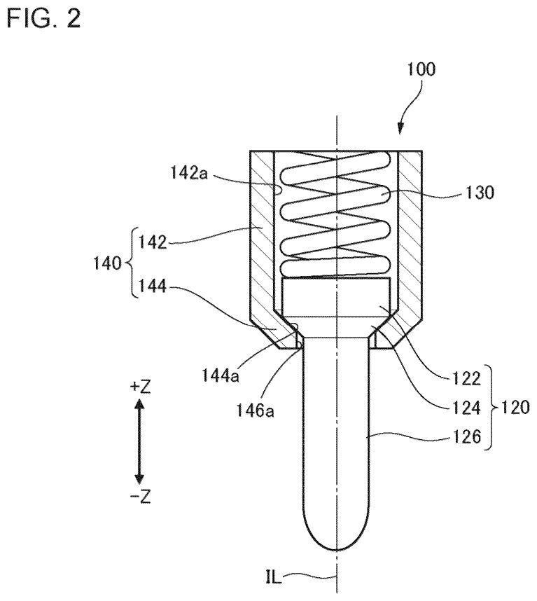

FIG. 1 is a cross-sectional view of a probe head 10 according to the embodiment. FIG. 2 is a cross-sectional view of a part of a probe 100 according to the embodiment. In the example shown in FIG. 1, an inspection object 20 and an inspection substrate 30 are electrically connected through the probe head 10. In FIGS. 1 and 2, for the sake of description, an imaginary line IL indicating a central axis of the probe 100 is depicted by a dash-dotted line.

In FIGS. 1 and 2, an arrow marked with “+Z” indicates a direction from a side where the inspection substrate 30 is located toward a side where the inspection object 20 is located. Specifically, in the embodiment, the arrow marked with “+Z” indicates a direction from a downward to an upward in a vertical direction. An arrow marked with “−Z” indicates a direction from a side where the inspection object 20 is located toward a side where the inspection substrate 30 is located. Specifically, in the embodiment, the arrow marked with “−Z” indicates a direction from the upward to the downward in the vertical direction. Hereinafter, as necessary, a direction perpendicular to the vertical direction will be referred to as a horizontal direction.

The probe head 10 will be described with reference to FIG. 1 and, if necessary, with reference to FIG. 2.

The probe head 10 includes the probe 100 and an insulating support 200. The probe 100 includes a first plunger 110, a second plunger 120, a coil spring 130, and a barrel 140. The insulating support 200 includes a lower insulating support 210 and an upper insulating support 220. At least a part of the insulating support 200 may be formed of a metal, or at least a part of a surface of an insulator may be covered with a metal.

The first plunger 110 is biased in a direction away from the second plunger 120 by the coil spring 130 shown in FIG. 2. Specifically, the first plunger 110 is biased upward. Accordingly, an upper end of the first plunger 110 can contact an electrode 22 of the inspection object 20 with the first plunger 110 biased upward.

The second plunger 120 is biased in a direction away from the first plunger 110 by the coil spring 130 shown in FIG. 2. Specifically, the second plunger 120 is biased downward. Accordingly, a lower end of the second plunger 120 can contact a pad 32 of the inspection substrate 30 with the second plunger 120 biased downward.

The barrel 140 extends substantially parallel to the vertical direction. The first plunger 110 is provided at an upper end of the barrel 140. The second plunger 120 is provided at a lower end of the barrel 140. The coil spring 130 shown in FIG. 2 is provided inside the barrel 140.

The lower insulating support 210 and the upper insulating support 220 are stacked in the vertical direction. The lower insulating support 210 is located below the upper insulating support 220. The lower insulating support 210 is, for example, a pin plate. The upper insulating support 220 is located above the lower insulating support 210. The upper insulating support 220 is, for example, a pin block. The lower insulating support 210 and the upper insulating support 220 support the barrel 140. Specifically, the barrel 140 is inserted into a through hole 202 provided in the lower insulating support 210 and the upper insulating support 220.

Next, details of the barrel 140 will be described with reference to FIG. 2. The barrel 140 includes a tube portion 142 and a locking portion 144.

The tube portion 142 is provided with a tube hole 142a. The tube hole 142a extends through at least a part of the tube portion 142 in the vertical direction. A diameter of the tube hole 142a in the horizontal direction is substantially constant regardless of a position of the tube hole 142a in the vertical direction.

The locking portion 144 is provided at a lower end of the tube portion 142. As will be described in detail below, the locking portion 144 locks the second plunger 120. As a result, the second plunger 120 is prevented from being removed downward from the barrel 140.

The locking portion 144 is provided with a tapered hole 144a. The tapered hole 144a extends through at least a part of the locking portion 144 in the vertical direction. An upper end of the tapered hole 144a communicates with a lower end of the tube hole 142a. A diameter of the upper end of the tapered hole 144a in the horizontal direction is substantially equal to a diameter of the lower end of the tube hole 142a in the horizontal direction. A diameter of the tapered hole 144a in the horizontal direction decreases downward.

An opening 146a is provided on a lower end surface of the locking portion 144. The opening 146a is open downward. An upper end of the opening 146a communicates with a lower end of the tapered hole 144a. A diameter of the upper end of the opening 146a in the horizontal direction is substantially equal to a diameter of the lower end of the tapered hole 144a in the horizontal direction. A diameter of the opening 146a in the horizontal direction is substantially constant regardless of a position of the opening 146a in the vertical direction. That is, an inner surface of the opening 146a is substantially parallel to the imaginary line IL. In a cross section shown in FIG. 2, the inner surfaces of the opening 146a on both sides in the horizontal direction appear. In a cross section shown in FIG. 2, the inner surfaces of the opening 146a on both sides in the horizontal direction are substantially parallel to each other.

As will be described in detail below with reference to FIGS. 4 to 7, the tube hole 142a, the tapered hole 144a, and the opening 146a are formed by machining. Similarly, at least a part of an outer surface of the barrel 140 is formed by machining.

Next, the second plunger 120 and the coil spring 130 will be described with reference to FIG. 2. The second plunger 120 includes a flange portion 122, a tapered portion 124, and a column portion 126.

The coil spring 130 is provided inside the tube hole 142a. The flange portion 122 is located below a lower end of the coil spring 130. A diameter of the flange portion 122 in the horizontal direction is substantially constant regardless of a position of the flange portion 122 in the vertical direction. The diameter of the flange portion 122 in the horizontal direction is less than the diameter of the tube hole 142a in the horizontal direction. Accordingly, the flange portion 122 is slidable in the vertical direction inside the tube hole 142a.

The tapered portion 124 is provided at a lower end of the flange portion 122. A diameter of an upper end of the tapered portion 124 in the horizontal direction is substantially equal to a diameter of the lower end of the flange portion 122 in the horizontal direction. A diameter of the tapered portion 124 in the horizontal direction decreases downward. The diameter of the upper end of the tapered portion 124 is equal to or greater than the diameter of the lower end of the tapered hole 144a. A diameter of a lower end of the tapered portion 124 is less than the diameter of the lower end of the tapered hole 144a. Thus, when the second plunger 120 is biased downward by the coil spring 130, at least a part of an outer surface of the tapered portion 124 contacts an inner surface of the tapered hole 144a. Accordingly, the tapered portion 124 can be prevented from being removed downward from the opening 146a. As a result, the locking portion 144 locks the tapered portion 124.

The column portion 126 is provided at the lower end of the tapered portion 124. The column portion 126 extends in the vertical direction. A diameter of an upper end of the column portion 126 in the horizontal direction is substantially equal to a diameter of the lower end of the tapered portion 124 in the horizontal direction. The diameter of the column portion 126 in the horizontal direction is substantially constant regardless of a position of the column portion 126 in the vertical direction except for a lower end of the column portion 126. The lower end of the column portion 126 is rounded. However, a shape of the lower end of the column portion 126 is not limited to this example. The diameter of the column portion 126 in the horizontal direction is less than the diameter of the opening 146a in the horizontal direction. As a result, the locking portion 144 allows the column portion 126 to protrude substantially parallel to the vertical direction from the opening 146a.

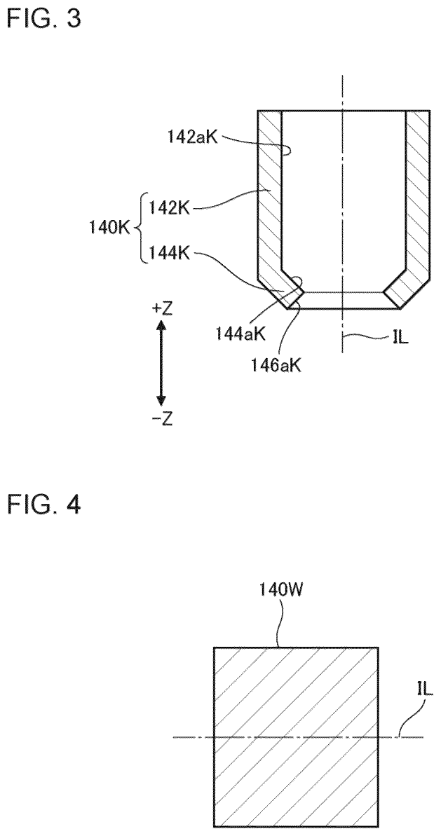

FIG. 3 is a cross-sectional view of a barrel 140K according to a comparative embodiment. The barrel 140K according to the comparative embodiment is similar to the barrel 140 according to the embodiment except for the following points.

The barrel 140K according to the comparative embodiment includes a tube portion 142K and a locking portion 144K. The tube portion 142K according to the comparative embodiment is provided with a tube hole 142aK. The locking portion 144K according to the comparative embodiment is provided with a tapered hole 144aK. An opening 146ak is provided on a lower end surface of the locking portion 144K according to the comparative embodiment. The locking portion 144K according to the comparative embodiment is formed by caulking a lower end of the barrel 140K. Thus, an inner surface of the opening 146aK according to the comparative embodiment is inclined with respect to the imaginary line IL. Specifically, a diameter of the opening 146aK according to the comparative embodiment in the horizontal direction increases downward.

The barrel 140 according to the embodiment and the barrel 140K according to the comparative embodiment will be compared.

In the comparative embodiment, the inner surface of the opening 146ak is inclined with respect to an axial direction of the second plunger 120. In the comparative embodiment, the axial direction of the second plunger 120 is substantially parallel to the imaginary line IL. In the embodiment, on the other hand, the inner surface of the opening 146a is substantially parallel to the axial direction of the second plunger 120. In the embodiment, the axial direction of the second plunger 120 is substantially parallel to the imaginary line IL. Accordingly, the column portion 126 is more easily to be aligned substantially parallel to the imaginary line IL by the inner surface of the opening 146a in the embodiment than the comparative embodiment. Thus, the inclination of the second plunger 120 with respect to the central axis of the probe 100 can be suppressed in the embodiment as compared to the comparative embodiment.

Further, the column portion 126 can be more easily aligned substantially parallel to the imaginary line IL in the embodiment than in the comparative embodiment even with reduced length of the flange portion 122 in the vertical direction. That is, when the length of the flange portion 122 in the vertical direction is equal to or greater than a certain length, the column portion 126 can be aligned substantially parallel to the imaginary line IL by contacting an outer surface of the flange portion 122 with an inner surface of the tube hole 142a. In the embodiment, as described above, the column portion 126 is easily aligned substantially parallel to the imaginary line IL by the inner surface of the opening 146a, which is substantially parallel to the imaginary line IL. Accordingly, the length of the flange portion 122 in the vertical direction according to the embodiment can shorter than a length of the flange portion 122 in the vertical direction according to the comparative embodiment. Accordingly, a length in the vertical direction of a space for disposing the coil spring 130 inside the tube hole 142a can be increased in the embodiment as compared to the comparative embodiment.

In the comparative embodiment, in a cross section shown in FIG. 3, an angle between a direction between an upper end and a lower end of an inner surface of the tapered hole 144aK and a direction between a lower end and an upper end of the inner surface of the opening 146aK is substantially a right angle. This is because the locking portion 144K according to the comparative embodiment is formed by caulking the lower end of the barrel 140K as described above. In the embodiment, on the other hand, in a cross section shown in FIG. 2, an angle between a direction between an upper end and a lower end of the inner surface of the tapered hole 144a and a direction between a lower end and an upper end of the inner surface of the opening 146a is an obtuse angle. Accordingly, abrasion of the tapered portion 124 due to an angle between the lower end of the inner surface of the tapered hole 144a and the upper end of the inner surface of the opening 146a can be suppressed in the embodiment as compared to the comparative embodiment.

FIGS. 4 to 7 are diagrams illustrating a method of manufacturing the barrel 140 according to the embodiment.

The barrel 140 according to the embodiment is manufactured as follows. Hereinafter, in the description using FIGS. 4 to 7, a direction substantially parallel to the imaginary line IL is referred to as an axial direction as necessary. Hereinafter, in the description using FIGS. 4 to 7, a direction substantially perpendicular to the imaginary line IL is referred to as a radial direction as necessary.

First, as shown in FIG. 4, a workpiece 140W is prepared. The workpiece 140W is, for example, made of a metal.

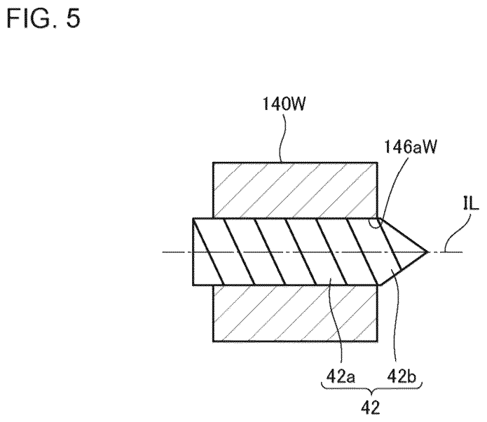

Next, as shown in FIG. 5, a small diameter drill 42 is allowed to pass through the workpiece 140W in the axial direction while the workpiece 140W is rotated around the imaginary line IL. The small diameter drill 42 includes a small diameter shaft portion 42a and a small diameter tip portion 42b. A diameter of the small diameter shaft portion 42a in the radial direction is substantially constant regardless of a position of the small diameter shaft portion 42a in the axial direction. The small diameter tip portion 42b is provided at a tip of the small diameter shaft portion 42a. A diameter of the small diameter tip portion 42b in the radial direction decreases toward a tip of the small diameter tip portion 42b. The small diameter tip portion 42b extends through the workpiece 140W in the axial direction. Accordingly, a small diameter hole 146aW is formed by machining with the small diameter shaft portion 42a. For this reason, a diameter of the small diameter hole 146aW in the radial direction is substantially equal to the diameter of the small diameter shaft portion 42a in the radial direction.

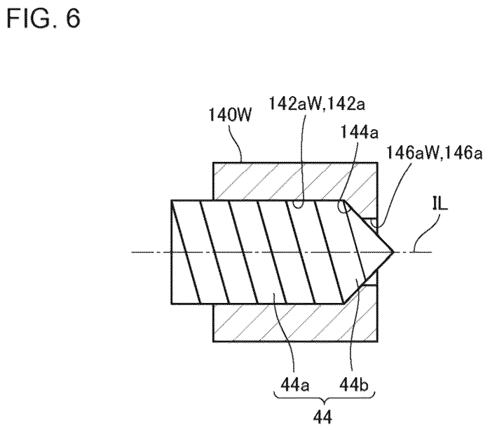

Next, as shown in FIG. 6, a large diameter drill 44 is allowed to pass through the small diameter hole 146aW in the axial direction while the workpiece 140W is rotated around the imaginary line IL. The large diameter drill 44 includes a large diameter shaft portion 44a and a large diameter tip portion 44b. A diameter of the large diameter shaft portion 44a in the radial direction is substantially constant regardless of a position of the large diameter shaft portion 44a in the axial direction. The diameter of the large diameter shaft portion 44a in the radial direction is greater than the diameter of the small diameter shaft portion 42a in the radial direction. The large diameter tip portion 44b is provided at a tip of the large diameter shaft portion 44a. A diameter of the large diameter tip portion 44b in the radial direction decreases toward a tip of the large diameter drill 44. The large diameter tip portion 44b extends through the workpiece 140W in the axial direction without a tip of the small diameter hole 146aW.

In the example shown in FIG. 6, the large diameter hole 142aW is formed by machining with the large diameter shaft portion 44a without the tip of the small diameter hole 146aW. Thus, a diameter of the large diameter hole 142aW in the radial direction is substantially equal to the diameter of the large diameter shaft portion 44a in the radial direction. The large diameter hole 142aW is a hole that becomes the tube hole 142a. Accordingly, a diameter of the tube hole 142a in the radial direction can be controlled by the diameter of the large diameter shaft portion 44a in the radial direction.

In the example shown in FIG. 6, the tapered hole 144a is formed by machining with the large diameter tip portion 44b. The inclination of the inner surface of the tapered hole 144a with respect to the imaginary line IL is substantially equal to the inclination of an outer surface of the large diameter tip portion 44b with respect to the imaginary line IL. That is, the inclination of the inner surface of the tapered hole 144a with respect to the imaginary line IL can be controlled by the inclination of the outer surface of the large diameter tip portion 44b with respect to the imaginary line IL. Thus, the inclination of the inner surface of the tapered hole 144a with respect to the imaginary line IL can be adjusted with high accuracy in the embodiment as compared to a case where the locking portion 144K is formed by caulking a tip of the barrel 140K in the comparative embodiment. Accordingly, the inclination of the inner surface of the tapered hole 144a with respect to the imaginary line IL is more easily aligned with the inclination of the outer surface of the tapered portion 124 with respect to the imaginary line IL in the embodiment as compared to the comparative embodiment. Accordingly, the inclination of the column portion 126 with respect to the imaginary line IL can be suppressed in the embodiment as compared to the comparative embodiment.

In the example shown in FIG. 6, a tip of the small diameter hole 146aW through which the large diameter tip portion 44b does not extend remains as the opening 146a. That is, the opening 146a is formed by machining with the small diameter shaft portion 42a. In the embodiment, the inner surface of the opening 146a can be accordingly aligned in a direction substantially parallel to the imaginary line IL. In the embodiment, a diameter of the opening 146a in the radial direction can be controlled by the diameter of the small diameter shaft portion 42a in the radial direction. Thus, the diameter of the opening 146a in the radial direction can be adjusted with high accuracy in the present embodiment as compared to a case where the locking portion 144K is formed by caulking the tip of the barrel 140K in the comparative embodiment. Accordingly, the inclination of the column portion 126 with respect to the imaginary line IL can be suppressed in the embodiment as compared to the comparative embodiment.

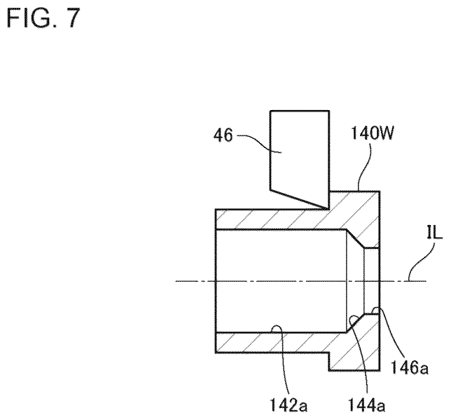

Next, as shown in FIG. 7, a tip of a blade 46 is pressed against an outer surface of the workpiece 140W to machine the outer surface of the workpiece 140W while the workpiece 140W is rotated around the imaginary line IL. Specifically, the outer surface of the workpiece 140W is machined in a direction substantially parallel to the imaginary line IL without a tip of the workpiece 140W. As a result, an outer surface of the tube portion 142 around the tube hole 142a in the axial direction is formed. At the tip of the workpiece 140W, the outer surface of the workpiece 140W is machined obliquely with respect to the imaginary line IL. As a result, an outer surface of the locking portion 144 around the tapered hole 144a and the opening 146a in the axial direction is formed. In the embodiment, a shape of the outer surface of the locking portion 144 around the tapered hole 144a and the opening 146a in the radial direction is adjusted with high accuracy as compared to a case where the locking portion 144K is formed by caulking the tip of the barrel 140K in the comparative embodiment, so that shapes of the outer surfaces of the locking portions 144 around the tapered hole 144a and the opening 146a in the radial direction can be made substantially the same even when manufacturing many barrels 140.

The method of manufacturing the barrel 140 is not limited to the method described above.

For example, in method described above, the small diameter drill 42, the large diameter drill 44, or the blade 46 is pressed against the workpiece 140W while the workpiece 140W is rotated around the imaginary line IL. However, the small diameter drill 42, the large diameter drill 44, or the blade 46 may be rotated around the imaginary line IL and pressed against the workpiece 140W.

In the embodiment, the small diameter hole 146aW is formed by pressing the small diameter drill 42 against the solid workpiece 140W. However, the workpiece 140W provided with the small diameter hole 146aW in advance may be prepared. In this case, the large diameter hole 142aW is formed by pressing the large diameter drill 44 against the workpiece 140W without using the small diameter drill 42.

In the embodiment, after forming the small diameter hole 146aW and the large diameter hole 142aW, the outer surface of the workpiece 140W is subjected to machining. However, the small diameter hole 146aW and the large diameter hole 142aW may be formed after machining the outer surface of the workpiece 140W.

Although the embodiments of the present invention have been described above with reference to the drawings, these are examples of the present invention, and various configurations other than the above can be adopted.

For example, in the embodiment, a structure of the locking portion that locks the second plunger has been described. However, the structure of the locking portion that locks the second plunger can also be applied to a locking portion that locks the first plunger.

According to this specification, the following aspects are provided.

### Aspect 1

Aspect 1 is a probe including:
a plunger; and
a barrel provided with an opening through which at least a part of the plunger protrudes,
in which an inner surface of the opening is substantially parallel to an axial direction of the plunger.

According to Aspect 1, the plunger is more easily aligned substantially parallel to a central axis of the probe by the inner surface of the opening as compared to a case where the inner surface of the opening is inclined with respect to the axial direction of the plunger. Accordingly, the inclination of the plunger with respect to the central axis of the probe can be suppressed in Aspect 1 as compared to a case where the inner surface of the opening is inclined with respect to the axial direction of the plunger.

### Aspect 2

Aspect 2 is the probe according to Aspect 1, in which at least a part of an outer surface of the barrel is formed by machining.

According to Aspect 2, the shape of the outer surface of the barrel can be adjusted with high accuracy as compared to a case where a locking portion is formed by caulking a tip of the barrel, so that shapes of the outer surfaces of the locking portions can be made substantially the same even when manufacturing many barrels.

### Aspect 3

Aspect 3 is the probe according to Aspect 1 or 2, in which the opening is formed by machining.

According to Aspect 3, the diameter of the opening can be adjusted with high accuracy as compared to a case where the locking portion is formed by caulking the tip of the barrel. Accordingly, the inclination of the plunger with respect to the central axis of the probe can be suppressed in Aspect 2 as compared to a case where the locking portion is formed by caulking the tip of the barrel.

### Aspect 4

Aspect 4 is the probe according to any one of Aspects 1 to 3, in which the barrel is provided with a tapered hole communicating with the opening, and
the tapered hole is formed by machining.

According to aspect 4, the inclination of the tapered hole with respect to the central axis of the probe can be adjusted with high accuracy as compared to a case where the locking portion is formed by caulking the tip of the barrel. Accordingly, the inclination of the plunger with respect to the central axis of the probe can be suppressed in Aspect 3 as compared to a case where the locking portion is formed by caulking the tip of the barrel.

### Aspect 5

Aspect 5 is a method of manufacturing a barrel, the method including forming a second hole in a predetermined first hole of a workpiece, the second hole having a diameter greater than a diameter of the first hole,
in which in the forming the second hole, the second hole extends through the workpiece without a tip of the first hole.

According to Aspect 5, the diameter of the opening provided in the locking portion can be adjusted with high accuracy as compared to a case where the locking portion is formed by caulking the tip of the barrel.

### Aspect 6

Aspect 6 is the method of manufacturing a barrel according to Aspect 5, further including forming the first hole in the workpiece.

According to Aspect 6, the diameter of the tip of the first hole can be adjusted with high accuracy as compared to a case where the locking portion is formed by caulking the tip of the barrel.

### Aspect 7

Aspect 7 is the method of manufacturing a barrel according to Aspect 5 or 6, further including machining at least a part of an outer surface of the workpiece around the first hole and the second hole.

According to Aspect 7, the shape of the outer surface of the workpiece around the first hole and the second hole can be adjusted with high accuracy as compared to a case where the locking portion is formed by caulking the tip of the barrel.

This application claims priority based on Japanese Patent Application No. 2022-49368 filed on Mar. 25, 2022, the entire content of which is incorporated herein by reference.

### REFERENCE SIGNS LIST

10 probe head, 20 inspection object, 22 electrode, 30 inspection substrate, 32 pad, 42 small diameter drill, 42a small diameter shaft portion, 42b small diameter tip portion, 44 large diameter drill, 44a large diameter shaft portion, 44b large diameter tip portion, 46 blade, 100 probe, 110 first plunger, 120 second plunger, 122 flange portion, 124 tapered portion, 126 column portion, 130 coil spring, 140, 140K barrel, 140W workpiece, 142, 142K tube portion, 142a, 142aK tube hole, 142aW large diameter hole, 144, 144K locking portion, 144a, 144aK tapered hole, 146a, 146aK opening, 146aW small diameter hole, 200 insulating support, 202 through hole, 210 lower insulating support, 220 upper insulating support, IL imaginary line

1. A probe comprising:
a plunger; and
a barrel provided with an opening through which at least a part of the plunger protrudes,
wherein an inner surface of the opening is substantially parallel to an axial direction of the plunger.

2. The probe according to claim 1,
wherein at least a part of an outer surface of the barrel is formed by machining.

3. The probe according to claim 1,
wherein the opening is formed by machining.

4. The probe according to claim 1,
wherein the barrel is provided with a tapered hole communicating with the opening, and
the tapered hole is formed by machining.
